(19) United States
(12) Patent Application Publication
(10) Pub. No.: US 2022/0293834 A1
(43) Pub. Date: Sep. 15, 2022

(54) DOUBLE-SIDED DISPLAY DEVICE

(71) Applicant: KYOCERA Corporation, Kyoto-shi, Kyoto (JP)

(72) Inventor: Ryoichi YOKOYAMA, Kakogawa-shi, Hyogo (JP)

(21) Appl. No.: 17/636,192

(22) PCT Filed: Aug. 21, 2020
(86) PCT No.: PCT/JP2020/031717

§ 371 Date: Feb. 17, 2022

(30) Foreign Application Priority Data
Aug. 22, 2019 (JP) 2019-152295

(51) Int. Cl. H01L 33/60; H01L 25/075

(52) U.S. Cl. CPC H01L 33/60; H01L 25/0753

(57) ABSTRACT

A double-sided display device includes a substrate including a transparent insulating material and having a first main surface and a second main surface opposite to the first main surface, at least one first light emitter and at least one second light emitter mounted on the first main surface of the substrate, a first reflector that reflects light emitted from the at least one first light emitter toward a side of the double-sided display device adjacent to the first main surface, and a second reflector that reflects light emitted from the at least one second light emitter toward a side of the double-sided display device adjacent to the second main surface.

### FIELD

The present disclosure relates to a double-sided display device for displaying information such as images on both a front side and a back side of a transparent board using light emitters such as micro-light-emitting diodes (LEDs) mounted in a matrix on the transparent board.

### BACKGROUND

A known double-sided display device is described in, for example, Patent Literature 1. The known double-sided display device includes a transparent display including self-luminous pixels to be transparent in a non-display area, and a display area definer that defines a front display area for front display and a back display area for back display in a display area on the transparent display.

### CITATION LIST

### Patent Literature

Patent Literature 1: Japanese Unexamined Patent Application Publication No. 2004-286990

### BRIEF SUMMARY

A double-sided display device according to one or more aspects of the present disclosure includes a substrate including a transparent insulating material and having a first main surface and a second main surface opposite to the first main surface, at least one first light emitter and at least one second light emitter mounted on the first main surface of the substrate, a first reflector surrounding the at least one first light emitter to reflect light emitted from the at least one first light emitter toward a side of the double-sided display device adjacent to the first main surface, and a second reflector surrounding the at least one second light emitter to reflect light emitted from the at least one second light emitter toward a side of the double-sided display device adjacent to the second main surface.

### BRIEF DESCRIPTION OF DRAWINGS

The objects, features, and advantages of the present invention will become more apparent from the following detailed description and the drawings.

FIG. 1 is a cross-sectional view of a first light emitter included in a double-sided display device according to a first embodiment of the present disclosure.

FIG. 2 is a cross-sectional view of a second light emitter included in the double-sided display device according to the first embodiment of the present disclosure.

FIG. 3 is a cross-sectional view of a second light emitter included in a double-sided display device according to a second embodiment of the present disclosure.

FIG. 4 is a cross-sectional view of a second light emitter included in a double-sided display device according to a third embodiment of the present disclosure.

FIG. 5 is a plan view of the first light emitters and the second light emitters included in pixels in the double-sided display device according to the first embodiment of the present disclosure, showing their arrangement.

FIG. 6A is a plan view of first light emitters and second light emitters included in pixels in a double-sided display device according to a fourth embodiment of the present disclosure, showing their arrangement.

FIG. 6B is a plan view of the first light emitters and the second light emitters included in the pixels in the double-sided display device according to the fourth embodiment of the present disclosure, showing their arrangement.

FIG. 7 is a schematic circuit diagram of the double-sided display device with the pixel arrangement in FIG. 6A.

FIG. 8 is a timing chart describing the drive timing of the double-sided display device having the circuit configuration in FIG. 7.

FIG. 9 is a schematic circuit diagram of the double-sided display device with the pixel arrangement shown in FIG. 6B.

FIG. 10 is a timing chart describing the drive timing of the double-sided display device having the circuit configuration in FIG. 9.

FIG. 11 is a cross-sectional view of a double-sided display device according to a fifth embodiment of the present disclosure.

FIG. 12 is an enlarged cross-sectional view of a portion around a first light emitter included in the double-sided display device shown in FIG. 11.

FIG. 13 is an enlarged cross-sectional view of a portion around a second light emitter included in the double-sided display device shown in FIG. 11.

### DETAILED DESCRIPTION

One or more embodiments of the present invention will now be described in detail with reference to the drawings.

The structure that forms the basis of a double-sided display device according to one or more embodiments of the present disclosure will be described first. A double-sided display device with the structure that forms the basis of the double-sided display device according to one or more embodiments includes a transparent display including self-luminous pixels to be transparent in a non-display area, and a display area definer that defines a front display area for front display and a back display area for back display in a display area on the transparent display.

The transparent display is driven by a scanning driver and a data driver using a matrix addressing scheme. The data driver includes a shift register that converts display data, which is input chronologically, to data with an output format for the transparent display. The display area definer includes an inversion signal output unit that outputs an inversion signal for reversing the direction in which the shift register included in the data driver shifts data.

When the inversion signal output unit outputs an inversion signal, the direction in which the data in the shift register is shifted is reversed, and the level of the display data to be output to the data driver is inverted. The information appearing on the front side before the shift direction is reversed then appears on the back side.

This structure allows the display device to display data on both the front side and the back side without generating display data separately for the front side and the back side to achieve double-sided display. However, the inversion signal output unit in the display area definer outputs an inversion signal that reverses the direction in which the shift register included in the data driver shifts data. The display data then appears in the front display area on the front side or the back display area on the back side included in the display area on the transparent display.

With this structure, the display device cannot display the display data on both the front display area and the back display area simultaneously or chronologically in parallel. In response to the above issue, a double-sided display device according to one or more embodiments of the present disclosure will now be described below.

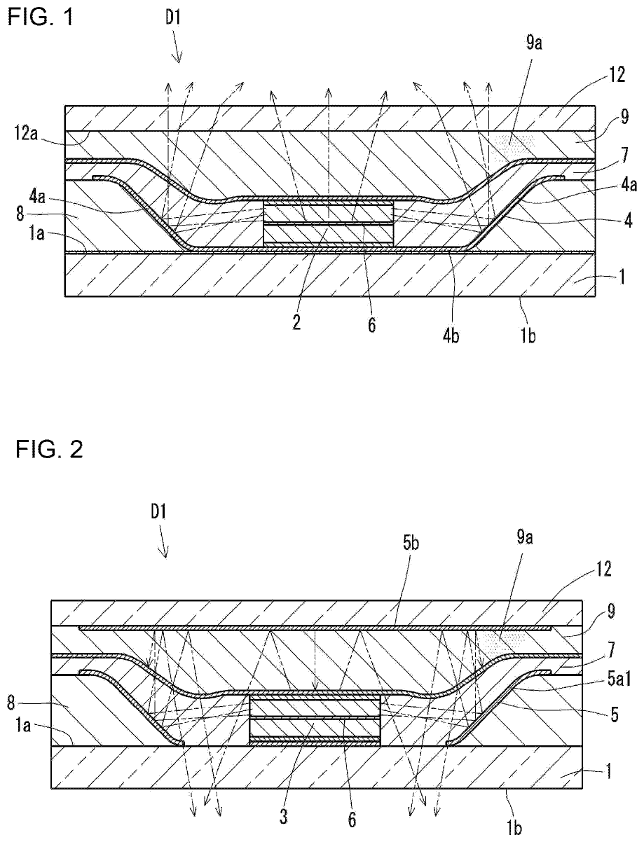

The double-sided display device according to an embodiment of the present disclosure will now be described with reference to FIGS. 1 and 2, schematically showing the display device. The figures referred to below are simplified for ease of explanation to show main components in the present embodiment but not to show known components, including a circuit board, a wiring conductor, a control integrated circuit (IC), and a large scale integration (LSI).

FIGS. 1 and 2 are cross-sectional views of a double-sided display device D1 according to a first embodiment of the present disclosure. The double-sided display device D1 includes a substrate 1 formed from an insulating material, first light emitters 2, second light emitters 3, first sloped reflectors 4a, first reflectors 4b, second relay reflectors Sal, second reflectors 5b, light shield layers 8, and a protective layer 12. In the present embodiment, the double-sided display device D1 includes the first sloped reflectors 4a and the first reflectors 4b to cause light to be emitted from a side of the double-sided display device D1 adjacent to a first main surface 1a, and the second relay reflectors 5a1 and the second reflectors 5b to cause light to be emitted from another side of the double-sided display device D1 adjacent to a second main surface 1b. However, the first sloped reflectors 4a and the second relay reflectors 5a1 may be eliminated when the first reflectors 4b and the second reflectors 5b alone allow a sufficient amount of light to be emitted.

The substrate 1 is formed from a transparent insulating material. The substrate 1 has the first main surface 1a and the second main surface 1b opposite to the first main surface 1a. Examples of the insulating material for the substrate 1 include glass, resin, and ceramic materials. The substrate 1 is rectangular as viewed in plan in the present embodiment. However, the substrate 1 may be circular, oval, trapezoidal, or in any other shape. The transparent insulating material may have a visible light transmittance of 70% or greater.

The first light emitters 2 and the second light emitters 3 are mounted on the first main surface 1a of the substrate 1. The first light emitters 2 and the second light emitters 3 in the present embodiment include mini- or micro-light-emitting diodes (LEDs). However, the first and second light emitters 2 and 3 may include organic electroluminescence (EL) elements or semiconductor laser elements.

Such micro-LEDs or other light emitters described above may be compound semiconductors. For example, II-VI compounds cover a wavelength range from blue to green, and III-V compound semiconductors cover a wavelength range from yellow to infrared. Group III nitrides among II-V compounds cover a wide wavelength range from visible to ultraviolet. Obtaining II-VI compounds uses lattice-matched epitaxial growth with molecular-beam epitaxy (MBE). Obtaining III-V compounds uses lattice-matched epitaxial growth with metalorganic chemical vapor deposition (MOCVD).

The first light emitters 2 and the second light emitters 3 each include an emissive layer 6. The emissive layer 6 emits light in all directions. The emissive layer 6 may be formed from a material such as InGaN or AlGaP.

The first light emitters 2 and the second light emitters 3 are each connected to a positive electrode and a negative electrode. In the present embodiment, the positive and negative electrodes are arranged above and below the light emitters 2 and 3. The positive and negative electrodes may be transparent electrodes formed from a transparent conductive material such as indium tin oxide (ITO).

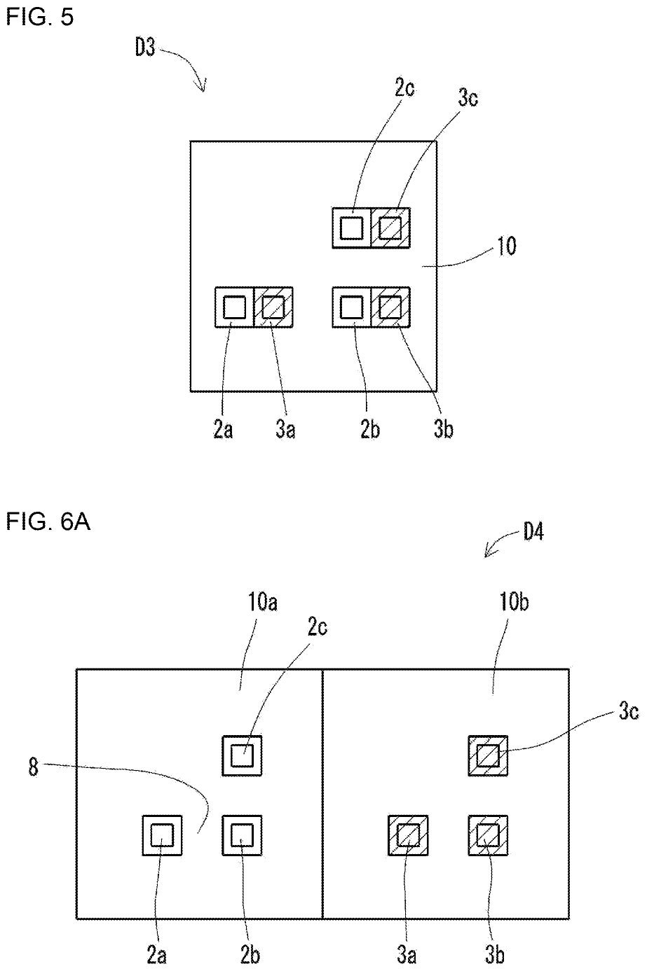

FIG. 5 shows multiple first light emitters 2 and second light emitters 3 arranged in a single pixel 10. A single pixel 10 may include multiple first light emitters 2 or a single first light emitter 2. The multiple first light emitters 2 may emit light of the same or different colors. Similarly, a single pixel 10 may include multiple second light emitters 3. The multiple second light emitters 3 may emit light of the same or different colors. For the first light emitters 2 and the second light emitters 3 capable of emitting different colors of light, these colors may be mixed to emit light of various colors.

In some embodiments, the first light emitters 2 and the second light emitters 3 may emit orange, red-orange, red-violet, or violet light, instead of red light. The first light emitters 2 and the second light emitters 3 may emit yellow-green light, instead of green light. In a single pixel 10 including three or more first light emitters 2 and three or more second light emitters 3, two or more first light emitters 2 and two or more second light emitters 3 may emit light of the same color.

As shown in FIG. 5, a single pixel 10 includes a first light emitter 2a that emits red light, a first light emitter 2b that emits blue light, and a first light emitter 2c that emits green light on the substrate 1. The single pixel 10 also includes a second light emitter 3a that emits red light, a second light emitter 3b that emits blue light, and a second light emitter 3c that emits green light. The second light emitters 3a, 3b, and 3c are each adjoining with the corresponding first light emitter 2 that emits light of the same color. The pixels 10 are arranged in a matrix on the substrate 1, forming an active matrix display device. The active matrix display device includes scanning lines and signal lines to write image data for display.

The light shield layers 8 of a light-shielding material are located between the first light emitter 2 and the second light emitter 3, between the first light emitters 2, and between the second light emitters 3. Each light shield layer 8 functions as a black matrix. The light shield layers 8 may include a light-shielding material that is dark colored, such as black, blackish brown, or dark blue. The dark colored light shield layers 8 allow the double-sided display device D to show a dark color or, for example, black on its background, thus increasing the contrast and the display quality of the double-sided display device D. The light shield layers 8 may be dark colored by, for example, mixing dark-colored ceramic particles or plastic particles, dark-colored pigments, or dark-colored dyes into the light shield layers 8. The light shield layers 8 are located between the first light emitter 2 and the second light emitter 3, between the first light emitters 2, and between the second light emitters 3 in the present embodiment. However, the light shield layers 8 may be light-transmissive rather than light-shielding. The light shield layers 8 may be light-shielding or light-transmissive when the light shield layers 8 each serve as a cavity structure including a cavity for emitting light from the light emitters outside. The light shield layers 8 may be hereinafter also referred to as cavity structures.

The reflector for the front display includes the first sloped reflector 4a and the first reflector 4b. The first sloped reflector 4a surrounds the first light emitter 2 adjacent to the first main surface 1a of the substrate 1. As shown in FIG. 1, the first sloped reflector 4a is laterally away from the first light emitter 2, and has its surface facing the first light emitter 2 at an angle with respect to a direction perpendicular to the first main surface 1a. The first reflector 4b is a flat plate between the first light emitter 2 and the substrate 1. The first sloped reflector 4a and the first reflector 4b are connected to each other on the first main surface 1a. This prevents light emitted from the first light emitter 2 from being emitted from the second main surface 1b of the substrate 1. The first sloped reflector 4a is located on the slope of the light shield film 8, or the cavity structure.

In FIG. 1, the path of light emitted from the first light emitter 2 is indicated by arrow lines. Light emitted from the first light emitter 2 is partly reflected from the surface of the first sloped reflector 4a lateral to the first light emitter 2 away from the first main surface 1a and toward the side of the display device adjacent to the first main surface 1a. Light emitted from the first light emitter 2 is also partly reflected from the first reflector 4b between the first light emitter 2 and the first main surface 1a and emitted outside from the side of the display device adjacent to the first main surface 1a through the transparent protective layer 12, which is located farther from the first main surface 1a than the first light emitter 2.

The first sloped reflector 4a, the first reflector 4b, a first relay reflector 4a1, a second sloped reflector 5a, the second reflector 5b, and the second relay reflector 5a1 may be formed from, for example, a metal material or an alloy material with a high light reflectance of visible light. Examples of the metal material include aluminum (Al), silver (Ag), gold (Au), chromium (Cr), nickel (Ni), platinum (Pt), and tin (Sn). Examples of the alloy material include duralumin (Al—Cu alloy, Al—Cu—Mg alloy, and Al—Zn—Mg—Cu alloy), which is an aluminum-based alloy. These materials have light reflectance of about 90 to 95% for aluminum, 93% for silver, 60 to 70% for gold, 60 to 70% for chromium, 60 to 70% for nickel, 60 to 70% for platinum, 60 to 70% for tin, and 80 to 85% for an aluminum alloy. Aluminum, silver, gold, and an aluminum alloy may be used for a light reflective film.

The first sloped reflector 4a, the first reflector 4b, the first relay reflector 4a1, the second sloped reflector 5a, the second reflector 5b, and the second relay reflector Sal, which are light reflective films, may be formed on an inner surface defining the cavity by thin film deposition, such as chemical vapor deposition (CVD), vapor deposition, or plating. The films may also be formed by thick film deposition, with which a resin paste containing particles of aluminum, silver, gold, or an aluminum alloy is fired and solidified. The first sloped reflector 4a, the first reflector 4b, the first relay reflector 4a1, the second sloped reflector 5a, the second reflector 5b, and the second relay reflector 5a1 may also be formed by bonding, with which a film containing aluminum, silver, gold, or an aluminum alloy is bonded to the inner surface of the cavity. A protective film may be located on the outer surface of the light reflective film to reduce oxidation of the light reflective film, which may cause a decrease in reflectance.

Light emitted from the first light emitter 2 is partly unreflected from the first sloped reflector 4a and the first reflector 4b and is directly emitted outside, or from the side of the display device adjacent to the first main surface 1a through the protective layer 12. The first sloped reflector 4a and the first reflector 4b on the substrate 1 efficiently cause the light from the first light emitter 2 to be emitted outside through the protective layer 12 on the side of the display device adjacent to the first main surface 1a.

The protective layer 12 may be formed from an insulating material such as glass, resin, or ceramic materials, and the material may be the same as or different from the material of the substrate 1.

The reflector for the back display includes the second relay reflector 5a1 lateral to the second light emitter 3 and the second reflector 5b located farther from the first main surface 1a than the second light emitter 3. The second reflector 5b is located on a surface 12a of the protective layer 12. The surface 12a faces the first main surface 1a.

The second relay reflector 5a1 lateral to the second light emitter 3 protrudes toward the side of the display device adjacent to the first main surface 1a. The second relay reflector Sal has its surface facing the second light emitter 3 at an angle with respect to a direction perpendicular to the first main surface 1a. The second reflector 5b located farther from the first main surface 1a than the second light emitter 3, or in other words, located on the surface 12a of the protective layer 12, is a flat plate. However, the second reflector 5b may be in any shape, including being spherically curved toward or away from the second light emitter 3 without reducing light reflection.

Light emitted laterally from the second light emitter 3 is reflected from the sloped surface of the second relay reflector 5a1 away from the first main surface 1a. The reflected light is then reflected from the second reflector 5b located farther from the first main surface 1a than the second light emitter 3 toward the first main surface 1a. The light is then emitted outside from the side of the display device adjacent to the second main surface 1b through the substrate 1.

The double-sided display device D1 may further include transparent filling layers 7. Each transparent filling layer 7 surrounds the first light emitter 2 to cover the first sloped reflector 4a and the first reflector 4b and protects the first light emitter 2. Similarly, the transparent filling layer 7 surrounds the second light emitter 3 to cover the second relay reflector Sal and protects the second light emitter 3. Any other transparent layer may be located between the transparent filling layer 7 and the first sloped reflector 4a or between the transparent filling layer 7 and the second relay reflector Sal. The transparent filling layer 7 is formed from a transparent resin including, for example, an acrylic resin and a polycarbonate resin.

The double-sided display device D1 may further include a planarizing resin layer 9. The planarizing resin layer 9 is located farther from the first main surface 1a than the first light emitter 2 and the second light emitter 3 and between the transparent filling layer 7 and the protective layer 12.

The planarizing resin layer 9 is formed from a transparent resin including, for example, an acrylic resin and a polycarbonate resin. The transparent filling layer 7 and the planarizing resin layer 9 may be formed from the same or different resin materials.

The structure may satisfy n1>n2>n2a>n3, where n1 is the refractive index of the emissive layers 6 in the first light emitter 2 and the second light emitter 3, n2 is the refractive index of the transparent filling layer 7 as a peripheral medium of the emissive layers 6, n2a is the refractive index of the planarizing resin layer 9 as a peripheral medium of the transparent filling layer 7, and n3 (=1) is the refractive index of air. In this structure, the critical angle of total internal reflection of light can be increased at the interface between each emissive layer 6 and the corresponding transparent filling layer 7. The critical angle of total internal reflection of light can also be increased at the interface between the transparent filling layer 7 and the planarizing resin layer 9. This improves the light extraction efficiency.

The planarizing resin layer 9 protects the first light emitter 2 and the second light emitter 3 as well as planarizes its surface away from the first main surface 1a, facilitating placement of other components, such as optical components.

The planarizing resin layer 9 may include light-scattering particles 9a being dispersed. The light-scattering particles 9a scatter the light traveling through the planarizing resin layer 9. The scattered light is then emitted outside. Examples of the material used for the light-scattering particles 9a include a transparent or an opaque material less likely to or unlikely to absorb light emitted from the emissive layer 6 and having a different refractive index from the planarizing resin layer 9. Examples of the transparent material used for the light-scattering particles 9a include silicon oxide (silica or SiO₂), titanium oxide (TiO₂), glass, and a resin. Examples of the opaque material used for the light-scattering particles 9a include metal such as aluminum or silver, an alloy such as stainless steel, and a ceramic material such as alumina (Al₂O₃).

Scattered light is mainly emitted outside, thus reducing uneven luminance. The light-scattering particles 9a may be dispersed, for example, to cause the planarizing resin layer 9 containing the dispersed light-scattering particles 9a to have a haze value of about 5 to 90%.

The double-sided display device D1 includes multiple pixels 10 arranged in a matrix. Each pixel 10 includes a mount area onto which the first light emitter 2 and the second light emitter 3 are mountable. In the present embodiment, as shown in FIG. 5, the first light emitters 2 and the second light emitters 3 are arranged on a single pixel 10. The first light emitter 2 and the second light emitter 3 rectangular as viewed in plan may have, but is not limited to, each side with a length of about 1 to 100 μm inclusive, or more specifically, about 10 to 50 μm inclusive.

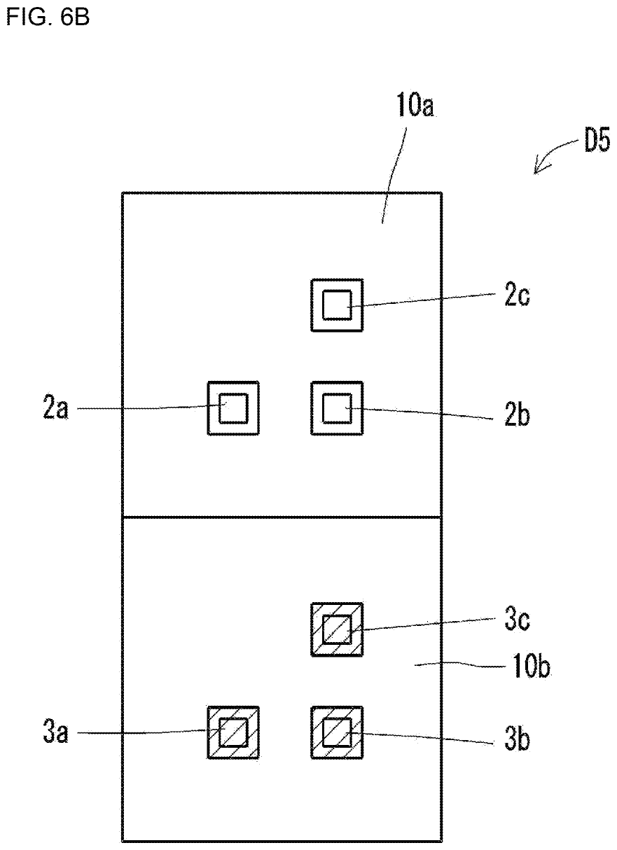

The first light emitters 2 and the second light emitters 3 may not be aligned on a single straight line as viewed in plan as shown in FIGS. 5, 6A, and 6B. In this case, the pixel 10 is smaller as viewed in plan and may be compact and square as viewed in plan. The display device or other devices thus include pixels with higher density and less irregularities, allowing high-quality image display.

In the double-sided display device D1, the light shield layers 8 may each function as a black matrix. Each light shield layer 8 may be light-shielding and dark colored, such as black, blackish brown, or dark blue. The dark colored light shield layer 8 allows the display device DS to show a dark color or, for example, black on its background, thus increasing the contrast and the display quality of the display device DS. The light shield layers 8 may be dark colored by, for example, mixing dark-colored ceramic particles or plastic particles, dark-colored pigments, or dark-colored dyes into the light shield layers 8.

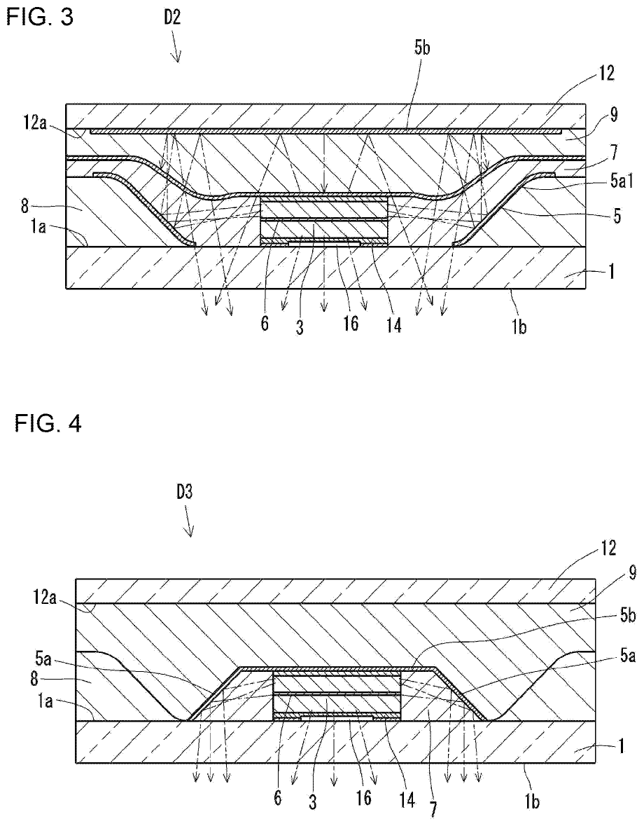

A double-sided display device D2 according to a second embodiment of the present disclosure will now be described with reference to FIG. 3. In the second embodiment, the same components as in the first embodiment are given the same reference numerals and are not described in detail. The double-sided display device D2 according to the present embodiment includes a transparent electrode 14 between a second light emitter 3 and a first main surface 1a. The transparent electrode 14 may be a positive electrode or a negative electrode. The transparent electrode 14 may be formed from any transparent conductive material, such as ITO or indium zinc oxide (IZO).

In the present embodiment, an electrode pad is partially arranged on the lower surface of the second light emitter 3, or the surface facing the first main surface 1a. The electrode pad thus defines a non-pad portion 16 to receive light under the second light emitter 3. The non-pad portion allows light emitted from the second light emitter 3 to travel outside efficiently, thus increasing the luminance on the side of the display device adjacent to the second main surface 1b.

A double-sided display device D3 according to a third embodiment of the present disclosure will now be described with reference to FIG. 4. The components corresponding to those in the above embodiments are given the same reference numerals and will not be described repeatedly.

The double-sided display device D3 according to the present embodiment includes a second reflector 5 including a portion (second reflector 5b) located farther from a first main surface 1a than a second light emitter 3. The second reflector 5b is located close to a surface of the second light emitter 3 facing in the same direction as the first main surface 1a. In other words, the second reflector 5b is located close to an electrode opposite to a transparent electrode 14 below the second light emitter 3. With the second reflector 5b shaped as above, light emitted from the second light emitter 3 is less likely to be strayed in a transparent filling layer 7 or a planarizing resin layer 9. Light emitted from the second light emitter 3 thus travels outside efficiently, increasing the luminance on the side of the display device adjacent to a second main surface 1b. In addition, the simple and space-saving structure allows the pixel pitch to be narrower. This achieves higher definition.

The double-sided display device D3 according to the embodiment of the present disclosure includes a first light emitter 2 and the second light emitter 3 separately driven by a drive 20. The display on the side of the display device adjacent to the first main surface 1a and the display on the side of the display device adjacent to the second main surface 1b, or the side opposite to the first main surface 1a across the substrate 1, can appear simultaneously or chronologically in parallel, thus allowing different images or other information to appear separately on the side of the display device adjacent to the first main surface 1a and on the side of the display device adjacent to the second main surface 1b.

Double-sided display devices D4 and D5 according to a fourth embodiment of the present disclosure will now be described with reference to FIGS. 6A and 6B. The components corresponding to those in the above embodiments are given the same reference numerals and will not be described repeatedly. First light emitters 2 and second light emitters 3 may be located in different areas adjoining with each other. In the double-sided display device D4 shown in FIG. 6A, the first light emitters 2 may be included in a pixel 10a and the second light emitters 3 may be included in a pixel 10b adjoining with the pixel 10a in a row direction. In the double-sided display device D5 shown in FIG. 6B, the first light emitters 2 may be included in a pixel 10a and the second light emitters 3 may be included in a pixel 10b adjoining with the pixel 10a in a column direction. In still another embodiment, three first light emitters 2 and three second light emitters 3 each emitting red, green, or blue (RGB) light may be arranged in each of the pixels 10a and 10b.

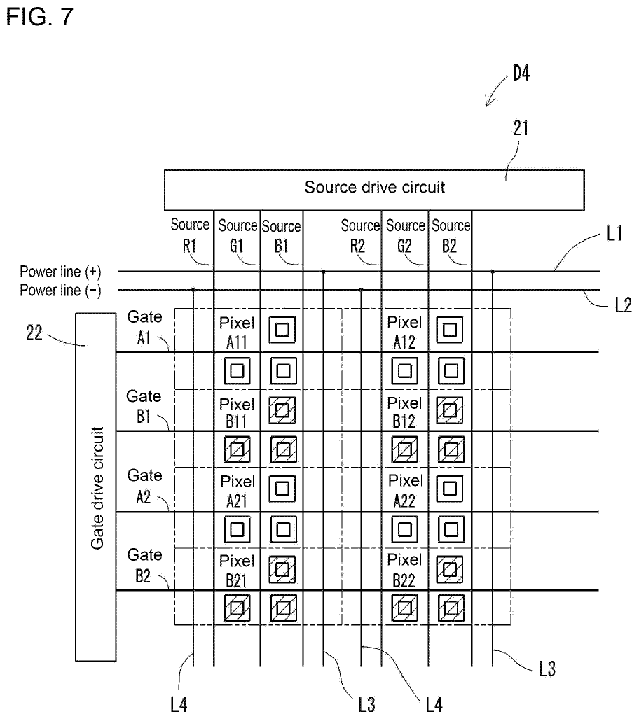

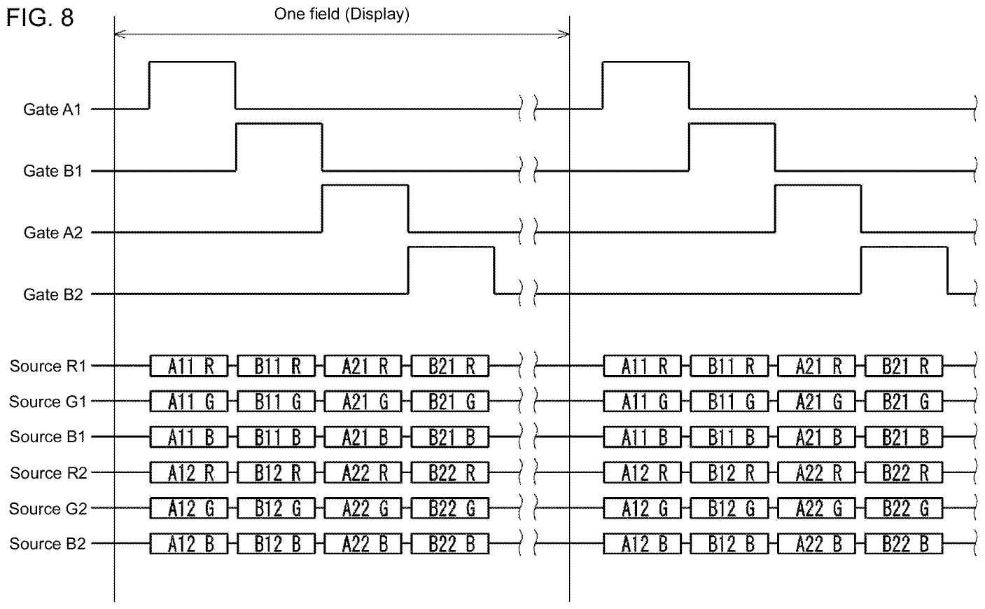

FIG. 7 is a schematic circuit diagram of the double-sided display device D4 with the pixel arrangement in FIG. 6A. FIG. 8 is a timing chart describing the drive timing of the double-sided display device D4 having the circuit configuration in FIG. 7. The components corresponding to those in the above embodiments are given the same reference numerals. The double-sided display device D4 with the pixel arrangement in FIG. 6A above includes sets of source lines R1, G1, and B1; R2, G2, and B2; . . . each corresponding to red, green, or blue arranged at intervals in the row direction (lateral direction in FIG. 7) and sets of gate lines A1 and B1; A2 and B2; . . . for the pixels 10 and 11 arranged at intervals in the column direction (vertical direction in FIG. 7).

The double-sided display device D4 with this structure includes a positive power line L1, a negative power line L2, positive power feed lines L3 each for feeding a drive voltage to the corresponding first light emitter 2 emitting red, green, or blue light on one pixel 10, and negative power feed lines L4 each for feeding a drive voltage to the corresponding second light emitter 3 emitting red, green, or blue on the other pixel 11. Each positive power feed line L3 is connected to the positive power line L1, and each negative power feed line L4 is connected to the negative power line L2.

The sets of source lines R1, G1, and B1; R2, G2, and B2; . . . are each connected to a source drive circuit 21. The sets of gate lines A1 and B1; A2 and B2; . . . are each connected to a gate drive circuit 22. The gate drive circuit 22 provides a scanning signal to each of the sets of gate lines A1 and B1; A2 and B2; . . . . The source drive circuit 21 then provides a driving signal to each of the sets of source lines R1, G1, and B1; R2, G2, and B2 and scans all the pixels per field. This allows simultaneous and individual display on the front and back sides in a direction perpendicular to the page of FIG. 7.

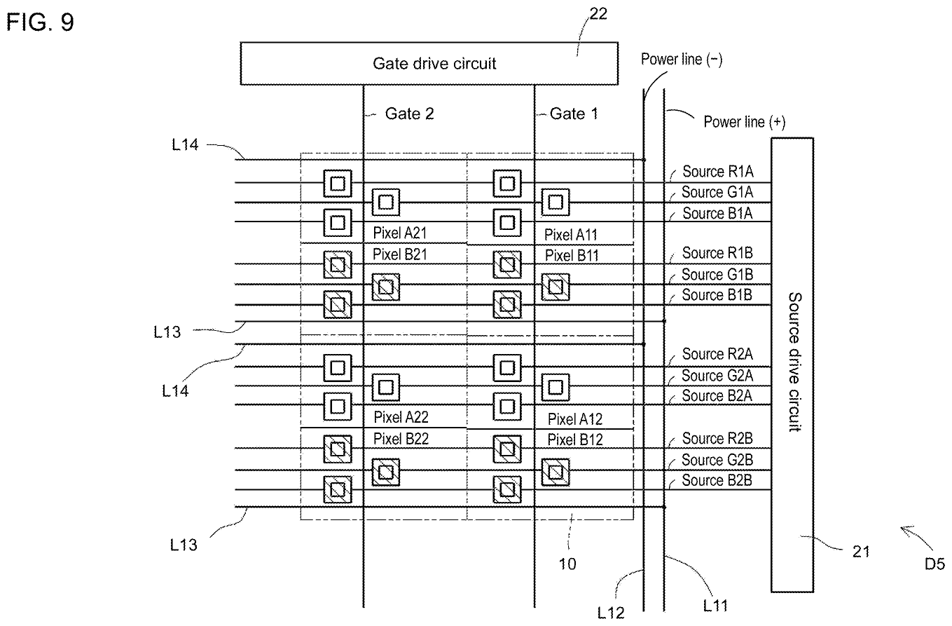

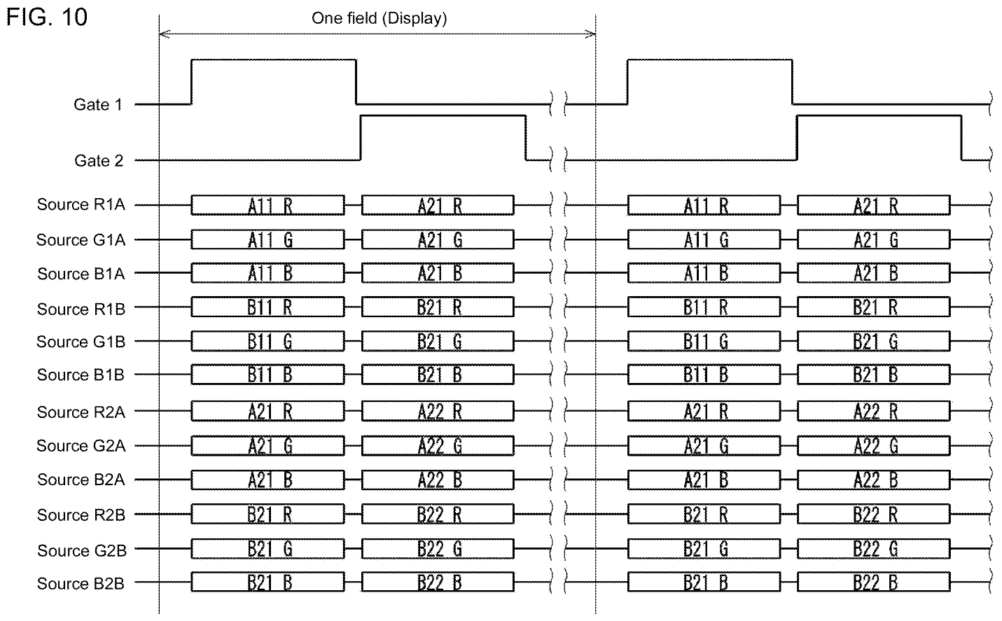

FIG. 9 is a schematic circuit diagram of the double-sided display device D5 with the pixel arrangement in FIG. 6B. FIG. 10 is a timing chart describing the drive timing of the double-sided display device D5 having the circuit configuration in FIG. 9. The components corresponding to those in the above embodiments are given the same reference numerals. The double-sided display device D5 with the pixel arrangement in FIG. 6B above includes sets of source lines R1A, G1A, and B1A; R2A, G2A, and B2A; . . . each corresponding to red, green, or blue arranged at intervals in the row direction and sets of gate lines A1 and B1; A2 and B2; . . . for the pixels 10 and 11 arranged at intervals in the column direction.

The double-sided display device D5 with this structure includes a positive power line L11, a negative power line L12, positive power feed lines L13 each for feeding a drive voltage to the corresponding first light emitter 2 or the second light emitter 3 on the pixels 10 and 11, and negative power feed lines L14 each for feeding a drive voltage to the corresponding first light emitter 2 or the second light emitter 3 on the pixels 10 and 11. Each positive power feed line L13 is connected to the positive power line L1, and each negative power feed line L14 is connected to the negative power line L2.

The sets of source lines R1, G1, and B1; R2, G2, and B2; . . . are each connected to the source drive circuit 21. The sets of gate lines A1 and B1; A2 and B2; . . . are each connected to the gate drive circuit 22. The gate drive circuit 22 provides a scanning signal to each of the sets of gate lines A1 and B1; A2 and B2; . . . . The source drive circuit 21 then provides a driving signal to each of the sets of source lines R1, G1, and B1; R2, G2, and B2 and scans all the pixels per field. This allows simultaneous and individual display on the front and back sides in a direction perpendicular to the page of FIG. 9.

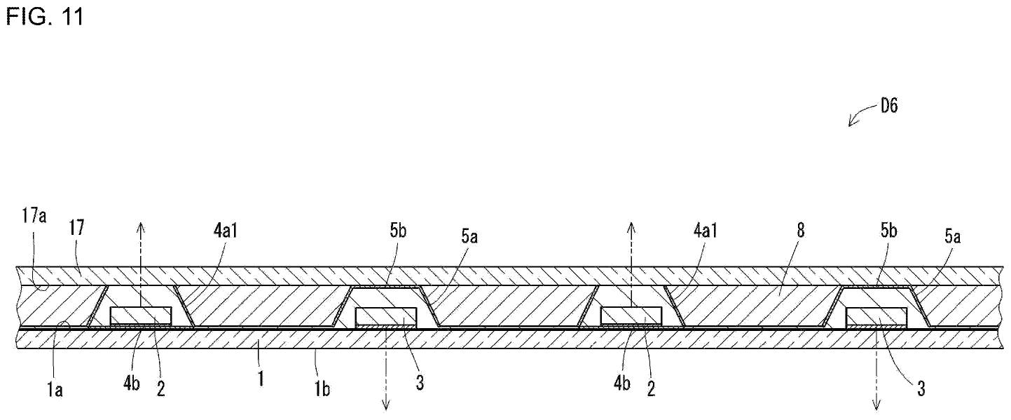

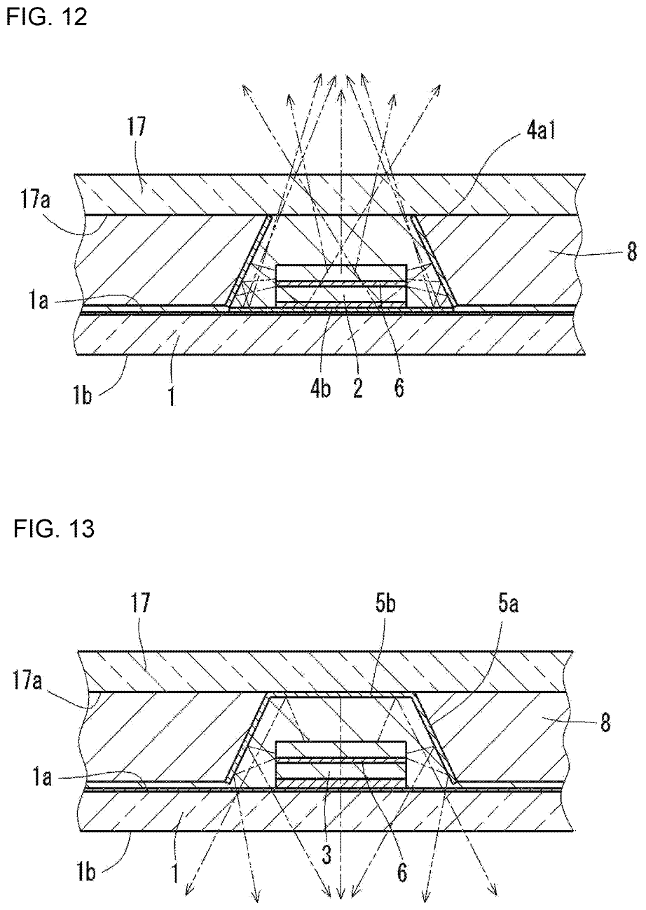

FIG. 11 is a partial cross-sectional view of a double-sided display device D6 according to a fifth embodiment of the present disclosure. FIG. 12 is an enlarged cross-sectional view of a portion around the first light emitter included in the double-sided display device D6 shown in FIG. 11. FIG. 13 is an enlarged cross-sectional view of a portion around the second light emitter included in the double-sided display device D6 shown in FIG. 11. The components corresponding to those in the above embodiments are given the same reference numerals.

The double-sided display device D6 according to the present embodiment includes a substrate 1 formed from a transparent insulating material and having a first main surface 1a and a second main surface 1b opposite to the first main surface 1a, a first light emitter 2 and a second light emitter 3 mounted on the first main surface 1a of the substrate 1, a first reflector 4b, a first relay reflector 4a1, a second reflector 5b, and a second sloped reflector 5a. The first reflector 4b is located between the first light emitter 2 and the first main surface 1a, and the second reflector 5b is located on a first main surface 17a of an opposing substrate 17, which is located farther from the first main surface 1a than the second light emitter 3. A cavity structure 8 including the first relay reflector 4a1 and the second reflector 5b may be light transmissive. A light reflective film may be formed on the cavity structure 8 in the opposing substrate 17 using a known technique.

Light from the first light emitter 2 is emitted from the side of the display device adjacent to the first main surface 1a through the opposing substrate 17. Light from the first light emitter 2 is also reflected from the first relay reflector 4a1 toward the first reflector 4b. The first reflector 4b causes the light to be emitted from the side of the display device adjacent to the first main surface 1a. Light from the second light emitter 3 is reflected from the second reflector 5b and emitted from the side of the display device adjacent to the second main surface 1b through the substrate 1. Light from the second light emitter 3 is also reflected from the second sloped reflector 5a and emitted from the side of the display device adjacent to the second main surface 1b through the substrate 1. The cavity structure is light transmissive, allowing intended data to appear on both sides of the display device. The display device except a portion including the pixels is transparent. The observer can thus view through to the other side of the double-sided display device.

The opposing substrate 17 is formed from a transparent insulating material, such as glass, resin, or ceramic materials similarly to the substrate 1. The opposing substrate 17 is rectangular as viewed in plan. However, the opposing substrate 17 may be rectangular, circular, oval, trapezoidal, or in any other shape as viewed in plan.

The double-sided display device D6 according to the present embodiment includes the first relay reflector 4a1 and the second sloped reflector 5a included in the opposing substrate 17 described above. In other embodiments, the opposing substrate 17 may include the first relay reflector 4a1 alone, the second sloped reflector 5a alone, or the second reflector 5b alone. In some embodiments, the opposing substrate 17 may include all of these components. The cavity accommodating the first light emitter 2 or the second light emitter 2 is filled with a filler such as a transparent resin. The filler may be located adjacent to the substrate 1 on which the first light emitter 2 or the second light emitter 3 is mounted or adjacent to the opposing substrate 17.

The double-sided display devices D1 to D6 according to the present embodiments each can be used as, for example, a printer head for an image formation device and other devices, an illumination device, a signboard, and a notice board. In particular, the structure according to the present disclosure may be installed in a vehicle, or specifically on a windshield or a rear glass, allowing appropriate display viewable on both sides of the structure comfortably. The structure is also installable on a glass window. In addition, the transparent substrate may be flexible and can thus be placed along a curved windshield or rear glass. The double-sided display device according to one or more embodiments of the present disclosure is not limited to the above embodiments and may include design alterations and improvements as appropriate.

The double-sided display devices D1 to D6 according to the present embodiments each include the first light emitter 2 and the second light emitter 3 separately driven by the drive 20. The display on the front side adjacent to the first main surface 1a and the display on the back side adjacent to the second main surface 1b can appear simultaneously or chronologically in parallel, allowing different images or other information to appear separately on the side adjacent to the first main surface 1a and on the side adjacent to the second main surface 1b opposite to the first main surface 1a across the substrate 1.

The present invention may be embodied in various forms without departing from the spirit or the main features of the present invention. The embodiments described above are thus merely illustrative in all respects. The scope of the present invention is defined not by the description given above but by the claims. Any modifications and alterations contained in the claims fall within the scope of the present invention.

### REFERENCE SIGNS LIST

1 substrate
1a first main surface
1b second main surface
2, 2a, 2b, 2c first light emitter
3, 3a, 3b, 3c second light emitter
4 first reflector
4a first sloped reflector
4a1 first relay reflector
4b first reflector
5a second sloped reflector
5a1 second relay reflector
5b second reflector
6 emissive layer
7 transparent filling layer
8 light shield layer
9 planarizing resin layer
9a light-scattering particle
10 pixel
11 transparent film
12 protective layer
16 non-pad portion
17 opposing substrate
20 drive
21 source drive circuit
22 gate drive circuit
D1 to D6 double-sided display device

1. A double-sided display device, comprising:
a substrate comprising a transparent insulating material, the substrate having a first main surface and a second main surface opposite to the first main surface;
at least one first light emitter and at least one second light emitter mounted on the first main surface of the substrate;
a first reflector configured to reflect light emitted from the at least one first light emitter toward a side of the double-sided display device adjacent to the first main surface; and
a second reflector configured to reflect light emitted from the at least one second light emitter toward a side of the double-sided display device adjacent to the second main surface.

2. The double-sided display device according to claim 1, wherein
the first reflector is located between the at least one first light emitter and the first main surface, and
the second reflector is located farther from the first main surface than the at least one second light emitter.

3. The double-sided display device according to claim 2, further comprising:
a first sloped reflector lateral to the at least one first light emitter; and
a second sloped reflector lateral to the at least one second light emitter.

4. The double-sided display device according to claim 2, further comprising:
a first relay reflector configured to reflect light emitted from the at least one first light emitter toward the first reflector; and
a second relay reflector configured to reflect light emitted from the at least one second light emitter toward the second reflector.

5. The double-sided display device according to claim 3, further comprising:
an opposing substrate located on the side of the double-sided display device adjacent to the first main surface,
wherein the opposing substrate includes the first sloped reflector.

6. The double-sided display device according to claim 4, further comprising:
an opposing substrate located on the side of the double-sided display device adjacent to the first main surface,
wherein the opposing substrate includes the first relay reflector.

7. The double-sided display device according to claim 3, further comprising:
an opposing substrate located on the side of the double-sided display device adjacent to the first main surface,
wherein the opposing substrate includes the second sloped reflector.

8. The double-sided display device according to claim 4, further comprising:
an opposing substrate located on the side of the double-sided display device adjacent to the first main surface,
wherein the opposing substrate includes the second relay reflector.

9. The double-sided display device according to claim 1, further comprising:
an opposing substrate located on the side of the double-sided display device adjacent to the first main surface,
wherein the opposing substrate includes the second reflector.

10. The double-sided display device according to claim 2, wherein
the second reflector is in contact with the at least one second light emitter.

11. The double-sided display device according to claim 1, wherein
the at least one first light emitter and the at least one second light emitter each include a micro-light-emitting diode.

12. The double-sided display device according to claim 1, wherein
the at least one first light emitter includes a plurality of first light emitters located on the first main surface, and each of the plurality of first light emitters emits light with a different color, and
the at least one second light emitter includes a plurality of second light emitters located on the first main surface, and each of the plurality of second light emitters emits light with a different color.

13. The double-sided display device according to claim 12, wherein
the plurality of first light emitters are located in a first area, and the plurality of second light emitters are located in a second area different from and adjoining with the first area.

14. The double-sided display device according to claim 1, further comprising:
a light dispersion layer between the at least one first light emitter and the first reflector and a light dispersion layer between the at least one second light emitter and the second reflector.
